(19) United States
(12) Patent Application Publication
(10) Pub. No.: US 2015/0008482 A1
(43) Pub. Date: Jan. 8, 2015

(54) SEMICONDUCTOR DEVICE AND MANUFACTURING METHOD THEREOF

(71) Applicant: KABUSHIKI KAISHA TOSHIBA, Tokyo (JP)

(72) Inventor: Motoyuki SATO, Yokkaichi-shi (JP)

(73) Assignee: KABUSHIKI KAISHA TOSHIBA, Tokyo (JP)

(21) Appl. No.: 14/179,287

(22) Filed: Feb. 12, 2014

(30) Foreign Application Priority Data
Jul. 5, 2013 (JP) 2013-141866

(51) Int. Cl. H01L 27/148; H01L 27/146

(52) U.S. Cl. CPC H01L 27/14806; H01L 27/14689
USPC 257/183.1; 438/60

(57) ABSTRACT

According to the embodiments, a semiconductor device having a CMOS image sensor is provided. The CMOS image sensor includes a plurality of photoelectric conversion units adapted to photoelectrically convert an incident light into signal charges; and a transfer unit adapted to transfer the signal charges generated by the photoelectric conversion unit to a floating diffusion unit from the photoelectric conversion unit. A channel portion of a transfer gate transistor of the transfer unit has at least one SiGe layer.

### CROSS-REFERENCE TO RELATED APPLICATIONS

This application is based upon and claims the benefit of priority from Japanese Patent Application No. 2013-141866, filed on Jul. 5, 2013; the entire contents of all of which are incorporated herein by reference.

### BACKGROUND OF THE INVENTION

1. Field of the Invention

The present embodiment generally relates to a semiconductor device and a manufacturing method thereof.

2. Description of the Related Art

In the progress of the manufacturing technique of semiconductor devices, disclosed is a CMOS image sensor technique for transferring electrons from a photodiode via a transfer gate to a floating diffusion for imaging.

In the conventional CMOS image sensor, however, when the electrons generated at the photodiode are transferred to the floating diffusion via the transfer gate, the electrons may be captured by the interface state existing in the Si/SiO₂ interface of the transfer gate. This may cause the random telegraph noise (RTN) and the phenomenon of the reduction of the number of saturated electrons, which results in the degradation of the pixel characteristics.

It is considered that the RTN of the MOSFET of the transfer gate is caused by fluctuation of the threshold voltage (Vth) that is caused by that the thermally excited carriers are randomly captured by and released from the defect state existing within the insulation film. The refinement of the MOSFET results in larger fluctuation of the Vth due to the captured carriers. The time (time constant) from the time when the carrier is captured by a trap to the time when it is released ranges wide from a few micro seconds to a few seconds, which is likely to be visually recognized as the random noise on the pixel.

As discussed above, in the conventional CMOS image sensor, the electrons transferred from the photodiode of the photoelectric conversion unit to the floating diffusion are likely to be captured by the interface state in the channel due to the interface state of the Si/SiO₂ interface of the transfer gate. Thus, there have been problems that the flicker of the image quality is caused due to the random telegraph noise and that the reduction of the dynamic range is caused due to the reduction in the number of saturated electrons.

### BRIEF DESCRIPTION OF THE DRAWINGS

FIG. 1 is a cross-sectional view schematically illustrating a configuration of a pixel unit of a semiconductor device to which a CMOS image sensor of a first embodiment is applied;

FIG. 2 is a schematic view illustrating a band structure of a channel portion of a transfer gate transistor of the CMOS image sensor;

FIG. 3 is a view illustrating a top view of the CMOS image sensor according to the first embodiment;

FIG. 4 is a view illustrating an example of a circuit configuration of the pixel unit of the CMOS image sensor according to the same embodiment;

FIG. 5A and FIG. 5B are views illustrating a motion of charges under the channel, FIG. 5A illustrates a transfer motion of the charges from a photodiode to a floating diffusion in the first embodiment, and FIG. 5B is a view illustrating the motion of the charge in the general MOSFET;

FIG. 6 is a view of the band structure of an interface;

FIG. 7 is a view schematically illustrating a crystallization state of a SiGe, Si interface;

FIG. 8A to FIG. 8E are process cross-sectional views illustrating a manufacturing process of the CMOS image sensor of the first embodiment;

FIG. 9A to FIG. 9C are process cross-sectional views illustrating a manufacturing process of the CMOS image sensor of the first embodiment;

FIG. 10 is a cross-sectional view schematically illustrating a structure of a pixel unit of a semiconductor device to which a CMOS image sensor of a second embodiment is applied;

FIG. 11A to FIG. 11E are process cross-sectional views illustrating a manufacturing process of the CMOS image sensor of the second embodiment;

FIG. 12A to FIG. 12C are process cross-sectional views illustrating a manufacturing process of the CMOS image sensor of the second embodiment;

FIG. 13 is a cross-sectional view schematically illustrating a structure of a pixel unit of a semiconductor device to which a CMOS image sensor of a third embodiment is applied;

FIG. 14 is a cross-sectional view schematically illustrating a structure of a pixel unit of a semiconductor device to which a CMOS image sensor of a fourth embodiment is applied; and

FIG. 15 is a cross-sectional view schematically illustrating a structure of a pixel unit of a semiconductor device to which a CMOS image sensor of a fifth embodiment is applied.

### DETAILED DESCRIPTION

According to the embodiments, provided is a semiconductor device including a CMOS image sensor. The CMOS image sensor has a plurality of photoelectric conversion units adapted to photoelectrically convert an incident light to signal charges, and a transfer unit adapted to transfer the signal charges generated by the photoelectric conversion unit to a floating diffusion unit from the photoelectric conversion unit. A channel portion of the transfer gate transistor of the transfer unit has at least one SiGe layer.

By referring to the attached drawings, the semiconductor device and the manufacturing method thereof according to the embodiments will be described in detail below. It is noted that the present invention is not limited by these embodiments.

### First Embodiment

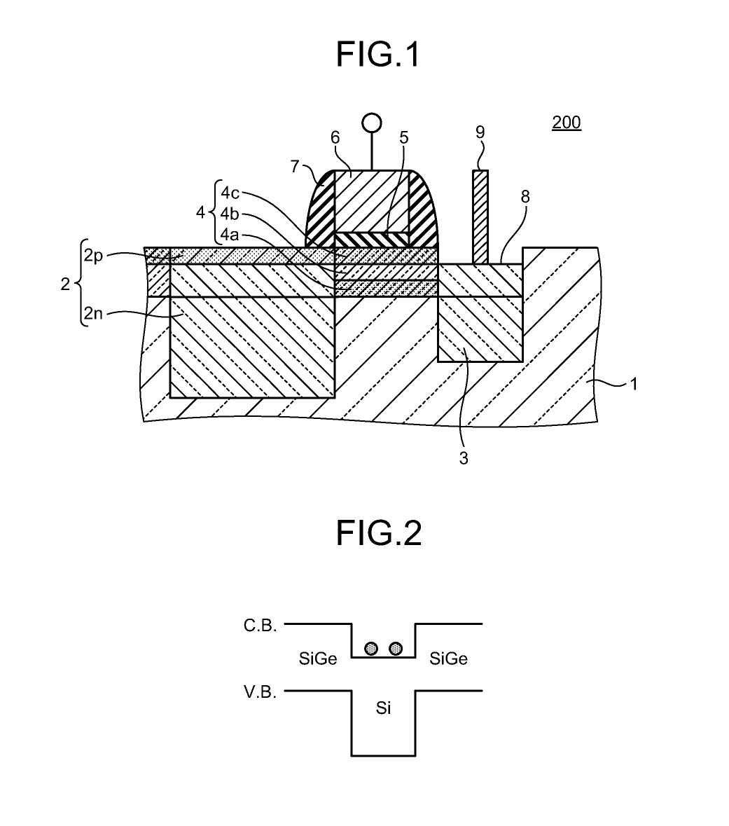

FIG. 1 is a cross-sectional view schematically illustrating the configuration of a pixel unit of a camera module (semiconductor device) to which the CMOS image sensor of the first embodiment is applied. FIG. 2 is a schematic view illustrating a band structure of a channel portion of the transfer gate transistor of the CMOS image sensor. In the present embodiment, in order to reduce the affection by the interface state existing in a Si/SiO₂ interface layer of the transfer gate transistor of the CMOS image sensor, a channel 4 is provided with a SiGe/Si/SiGe layered structure made of a SiGe layer 4a, a Si layer 4b, and a SiGe layer 4c in this order from the lower layer side. This structure allows the electrons to be transferred through non-defective Si layer 4b as a transfer path.

Since the conductive band of SiGe is in upper level than that of Si, the SiGe/Si/SiGe structure is a quantum well structure in which the Si layer 4b is interposed between the SiGe layer 4a and the SiGe layer 4c. Through this quantum well, the electrons are transferred from a photodiode unit 2 to a floating diffusion unit 3. As discussed above, the charge transfer path configures the quantum well structure and therefore the transferred electrons remain in the Si interposed between the SiGes, so that the electrons can be transferred without captured by the interface state of the semiconductor/SiO₂ interface, which allows for forming the CMOS image sensor with a superior pixel characteristics. Further, although not only the SiO₂/Si interface but also the interface state of the SiO₂/Si interface of a sidewall 7 will cause a dark current and a white defect, these defects will be distant from the Si transfer path, which can prevent the carriers generated from the defect from entering the transfer path and thus contribute to the suppression of the dark current and the white defect.

In contrast, when the interface state due to the crystal defect occurs in an end surface (hereafter, referred to as “receiving surface”) of the side which the incident light to the photodiode unit 2 enters, the electrons transferred from the photodiode unit to the floating diffusion unit are captured in the interface state in the channel, which may cause the flicker of the image quality due to the random telegraph noise and the reduction of the dynamic range due to the reduction of the number of saturated electrons. Therefore, in the CMOS image sensor 100, provided is a pixel unit 200 that is able to reduce the random telegraph noise and expand the dynamic range.

Next, by referring to FIG. 1, the configuration of the pixel unit 200 according to the embodiment will be described in detail.

FIG. 1 is an illustrative cross sectional view illustrating a part of the pixel unit 200 according to the embodiment. It is noted that FIG. 1 selectively illustrates the components near the photodiode unit 2 and the transfer gate 6 out of the components included in one pixel of the pixel unit 200, while depiction is omitted for a reset transistor, an amplifier transistor, an address selection transistor, and so on.

As illustrated in FIG. 1, each pixel portion of the pixel unit 200 includes a semiconductor region 1 of a first conductive type, the photodiode unit 2 formed in the semiconductor region 1 and made of an impurity diffusion layer of a second conductive type, the floating diffusion unit 3, a gate insulating film 5, and the transfer gate 6. On the surface of the floating diffusion unit 3, a contact unit 8 is formed and a contact plug 9 is formed. Further, on the sidewall of the transfer gate 6, a sidewall 7 is formed. Furthermore, each pixel portion of the pixel unit 200 includes, though not-illustrated, an anti-reflection film, an interlayer insulating film, a multi layer wiring, a color filter, a micro-lens, and so on.

In the CMOS image sensor, the electrons may be captured by the interface state existing in the Si/SiO₂ interface of the transfer gate 6 when the electrons generated at the photodiode unit 2 are transferred to the floating diffusion unit 3 via the transfer gate 6. This results in the occurrence of the phenomenon of causing the random telegraph noise and the reduction of the number of saturated electrons, and thus there is a problem of degradation of the pixel characteristics. Further, not only the SiO₂/Si interface but also the interface state of the SiO₂/Si interface of the sidewall 7 may cause the dark current and the white defect.

Therefore, in the present embodiment, in order to reduce the affection by the interface state existing in the Si/SiO₂ interface layer of the transfer gate transistor of the CMOS image sensor, the channel 4 is provided with a SiGe/Si/SiGe structure made of the SiGe layer 4a, the Si layer 4b, and the SiGe layer 4c in this order from the lower layer side. Since the conductive band of SiGe is in upper level than that of Si, the SiGe/Si/SiGe structure is a quantum well structure in which the Si layer 4b is interposed between the SiGe layer 4a and the SiGe layer 4c. Through this quantum well, the electrons are transferred from the photodiode unit 2 to the floating diffusion unit 3.

According to the present embodiment, the channel 4 is the SiGe/Si/SiGe layered structure made of the SiGe layer 4a, the Si layer 4b, and the SiGe layer 4c. Thus, the electrons are concentrated in the Si layer 4b and are physically distant from the semiconductor/SiO₂ interface, so that the affection of the interface state is mitigated. As a result, the CMOS image sensor with reduced random telegraph noise and expanded dynamic range can be obtained.

The semiconductor region 1 (hereafter, referred to as “p-well 1”) of the first conductive type (hereafter, referred to as “p-type”) is provided on the semiconductor substrate. The transfer gate 6 is provided at a predetermined position on the top surface of the p-well 1 via a gate insulating film 5. The sidewall 7 is provided to the side surface of the transfer gate 6.

The photodiode unit 2 is provided to the region neighboring one of the side surfaces of the transfer gate 6 in the p-well 1 in the top view, and includes a charge accumulating layer 2n of the second conductive type (hereafter, referred to as “n-type”) and a p-type semiconductor layer (hereafter, referred to as “hole accumulating layer 2p”) that accumulates holes. Such photodiode unit 2 is a photodiode formed by a pn junction of the charge accumulating layer 2n and the hole accumulating layer 2p, and photoelectrically converts the incident light from a not-illustrated micro-lens into an amount of electrons corresponding to the light amount to accumulate them in the charge accumulating layer 2n.

The transfer gate 6 functions as a gate that transfers electrons to the floating diffusion unit 3 from the charge accumulating layer 2n when a predetermined gate voltage is applied. The floating diffusion unit 3 temporarily stores the electrons transferred from the charge accumulating layer 2n.

Such pixel unit 200 photoelectrically converts the incident light into the electrons by the photodiode unit 2 and stores them in the charge accumulating layer 2n as the signal charge. When the gate voltage is applied to the transfer gate 6, the pixel unit 200 then performs transferring from the charge accumulating region 2n of the photodiode unit 2 to the floating diffusion unit 3. The signal charges transferred to the floating diffusion unit 3 are amplified by a not-illustrated amplifier transistor, and are read out to a peripheral circuit unit 300 as a pixel signal when a not-illustrated address selection transistor is selected, which is used as the intensity information of one pixel when the photographed image is generated.

As illustrated in FIG. 1, the photodiode unit 2 of the pixel unit 200 includes the hole accumulating layer 2p of the SiGe layer on the top surface of the charge accumulating region 2n. Because of the existence of the hole accumulating layer 2p of the SiGe layer having a high band gap, the photodiode unit 2 prevents the leak of the charges when the interface state due to the pollution of the light receiving surface and/or the crystal defect causes the excitation of the electrons which do not relate to the presence/absence of the incident light, so that the excited electron and the hole of the hole accumulating layer 2p can be further firmly re-coupled.

Therefore, the pixel unit 200 is able to suppress the situation that the electrons excited regardless of whether or not there is an incident light are transferred to the photodiode unit 2 as the dark current, which allows for the suppression of the occurrence of the white defect due to the dark current during photographing.

Further, in the present embodiment, the SiGe/Si/SiGe is omitted in the floating diffusion unit 3. This can prevent that, when the electrons are transferred from the floating diffusion unit 3 to the amplifier transistor, the electronic barrier occurs and causes not only the reduction of the transfer rate but also the situation where the full transfer cannot be made.

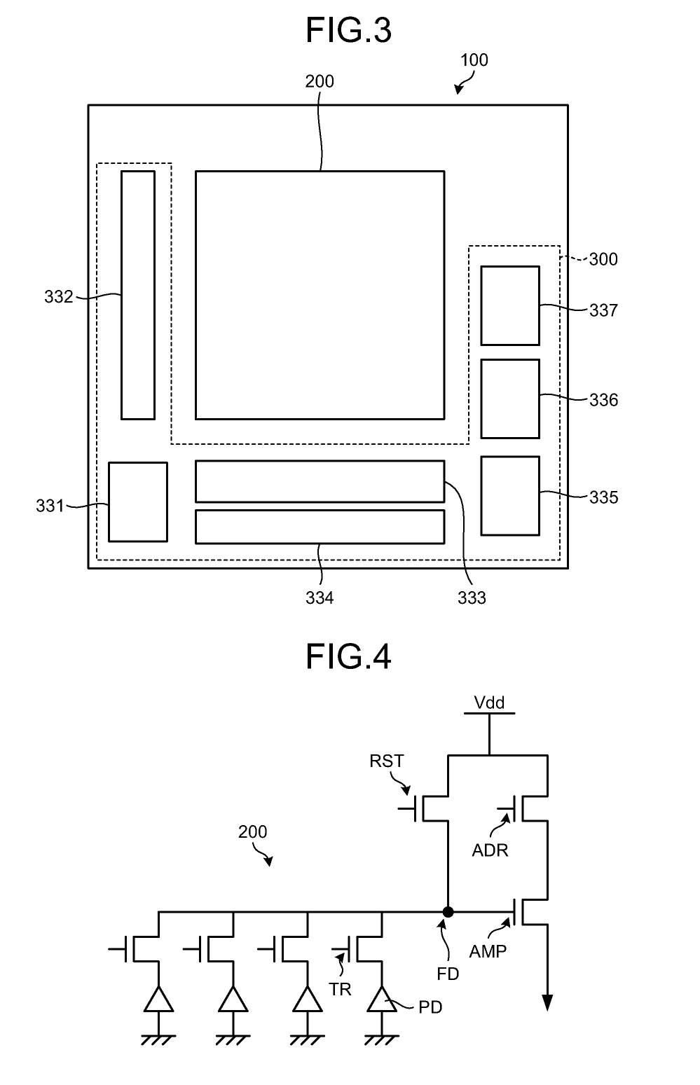

FIG. 3 is a view illustrating a top view of the CMOS image sensor according to the embodiment. As illustrated in FIG. 3, the CMOS image sensor 100 includes the pixel unit 200 and the peripheral circuit unit 300. FIG. 4 is a view illustrating an example of the circuit configuration of the pixel unit 200 of the CMOS image sensor according to the same embodiment.

As illustrated in FIG. 4, the pixel unit 200 is provided with four photodiode units PDs and transfer transistors TRs in a matrix for one unit. Furthermore, the pixel unit 200 includes a floating diffusion unit FD, an amplifier transistor AMP, a reset transistor RST, and an address transistor ADR. Each of such photodiode units PDs photoelectrically converts the incident light into the charges (here, electrons) corresponding to the amount of the receiving light (receiving light intensity) and accumulates them from the charge accumulating layer 2n to the floating diffusion unit FD (3).

In the peripheral circuit unit 300, analog circuits and/or logic circuits are included. Specifically, the peripheral circuit unit 300 includes a timing generator 331, a vertical selection circuit 332, a sampling circuit 333, a horizontal selection circuit 334, a gain control circuit 335, an A/D (analog/digital) conversion circuit 336, an input and output circuit 337, and so on.

The timing generator 331 is a processing unit that outputs a pulse signal that is the reference of the operation timing to the pixel unit 200, the vertical selection circuit 332, the sampling circuit 333, the horizontal selection circuit 334, the gain control circuit 335, the A/D conversion circuit 336, the input and output circuit 337, and so on.

The vertical selection circuit 332 is a processing unit that sequentially selects the floating diffusion unit 3 for reading out the charges on a row basis out of the floating diffusion units 3 connected to the plurality of photodiode units 2 arranged in a matrix. Such vertical selection circuit 332 outputs the charges that have been accumulated in each floating diffusion unit 3 selected on a row basis to the sampling circuit 333 from the photodiode unit 2 as the pixel signal indicating the intensity of each pixel.

The sampling circuit 333 is a processing unit that removes noises by a correlated double sampling (CDS) from the pixel signal inputted from each photodiode unit 2 selected on a row basis by the vertical selection circuit 332.

The horizontal selection circuit 334 is a processing unit that sequentially reads out on a column basis the pixel signal held by the sampling circuit 333 and outputs it to the gain control circuit 335. The gain control circuit 335 is a processing unit that adjusts the gain of the pixel signal inputted from the horizontal selection circuit 334 and outputs it to the A/D conversion circuit 336.

The A/D conversion circuit 336 is a processing unit that converts the analog pixel signal inputted from the gain control circuit 335 into the digital pixel signal and outputs it to the input and output circuit 337. The input and output circuit 337 is a processing unit that outputs the digital signal inputted from the A/D conversion circuit 336 to a predetermined digital signal processor (DSP (not-depicted)).

As described above, the CMOS image sensor 100 takes an image by that a plurality of the photodiode units 2 arranged in the pixel unit 200 photoelectrically convert the incident light into an amount of charges corresponding to the receiving light amount and accumulate them in the electron accumulating layer 2n and that the peripheral circuit unit 300 reads out the charges accumulated in each floating diffusion unit 3 as the pixel signal.

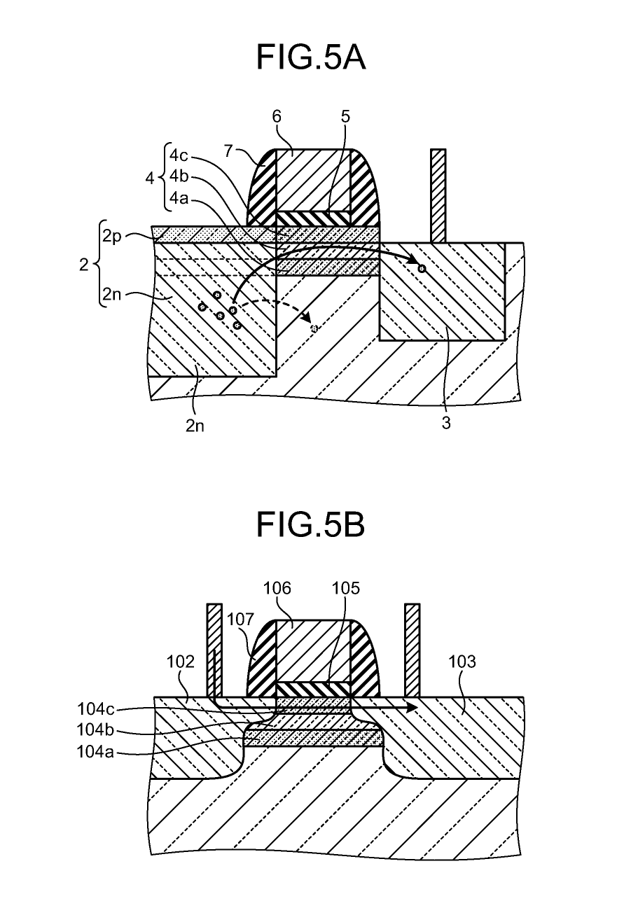

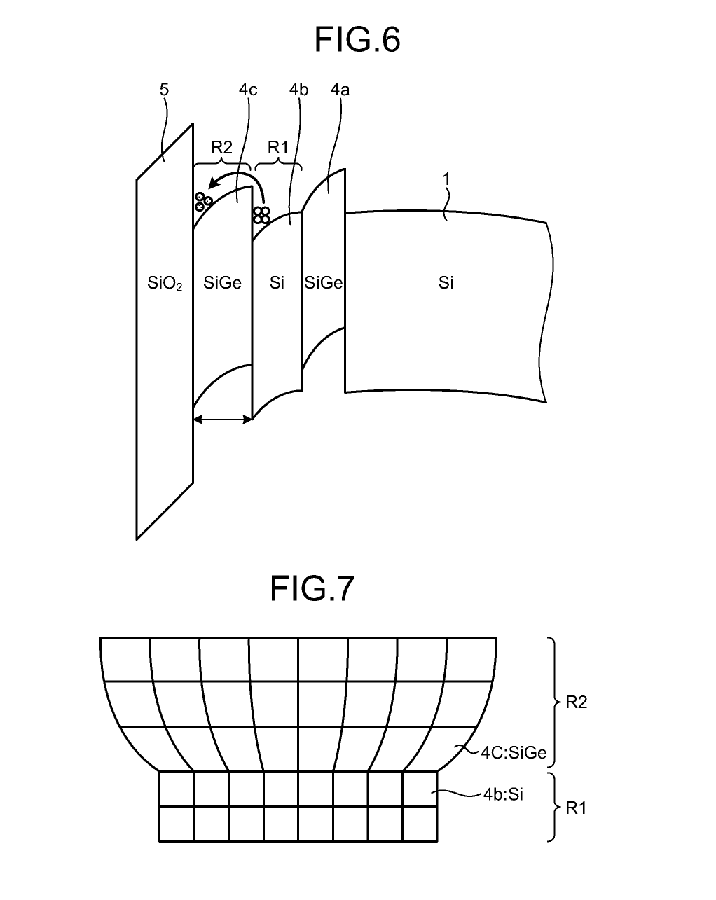

FIG. 5A is a schematic view illustrating a motion of the charges near the transfer gate in the CMOS image sensor 100 of the present embodiment. FIG. 5B is a schematic view illustrating a motion of the charge from the source 102 of the MOSFET to the drain 103 illustrating for the purpose of comparison. The element 104a represents a SiGe layer, the element 104b represents a Si layer, the element 104c represents a SiGe layer, the element 105 represents a gate insulating film, the element 106 represents a gate electrode, and the element 107 represents a sidewall. As illustrated in FIG. 5A, in the CMOS image sensor of the present embodiment, the charges generated in the deep region of the diffusion layer of the photodiode unit 2 are transferred to the floating diffusion unit 3 without leaking in the Si layer 4b (the region R1 of FIG. 6 and FIG. 7) of the quantum well. In contrast, as seen in the MOSFET, the charges supplied onto the surface of the source 102 are carried via the SiGe layer 104c (the region R2 of FIG. 6 and FIG. 7) near the surface as illustrated in FIG. 5B.

In addition to the comparison of FIG. 5A and FIG. 5B, as is clear also from the band structure diagram of FIG. 6, while the transfer path of the charges is the Si Layer 4b in the transfer gate transistor of the present embodiment, the transfer path of the charges is the SiGe layer 104c on the top surface in the MOSFET of FIG. 5B. In the present embodiment, in order to reduce the affection of the interface state existing in the Si/SiO₂ interface layer of the transfer gate transistor, the channel is provided with the SiGe/Si/SiGe structure and thus the transfer path of the charges is inside the Si layer 4b of the quantum well. Therefore, the depth of the Si layer, even if it is deep, allows for the adequate transferring and thus the conductive band of the SiGe exists in the upper level than the Si, so that the quantum well structure of SiGe/Si/SiGe is provided in which the Si is interposed between the SiGes. Therefore, the electrons are concentrated in the Si and are physically distant from the semiconductor SiO₂ interface, so that the affection of the interface state is mitigated.

Further, as seen in the crystal state of the SiGe, Si interface schematically illustrated in FIG. 7, although the SiGe is larger than the Si in the lattice constant and thus is subjected to the lattice distortion at the interface, the Si quantum well layer can be formed in a sufficiently deep position when the thickness of the SiGe is increased and it is formed with lattice relaxation. It is desirable that the thickness of the SiGe layer 4c in the present embodiment be 30 to 100 nm. This allows for reducing the lattice distortion due to the lattice relaxation and obtaining the transfer path with a high reliability. It is further desirable that the thickness of the SiGe layer of the uppermost surface side be thicker than 50 nm. This ensures the reduction of the lattice distortion. In contrast, in the MOSFET as illustrated in FIG. 5B, it is expected that the channel speed is increased due to the lattice distortion. It is generally known that the thickness of the SiGe layer 104c is desirably 5 to 100 nm, more desirably less than or equal to 50 nm. The thickness exceeding 50 nm can prevent the reduction of the channel speed due to the lattice distortion.

The present embodiment allows for the fabrication of the CMOS image sensor that is able to reduce the random telegraph noise and expand the dynamic range.

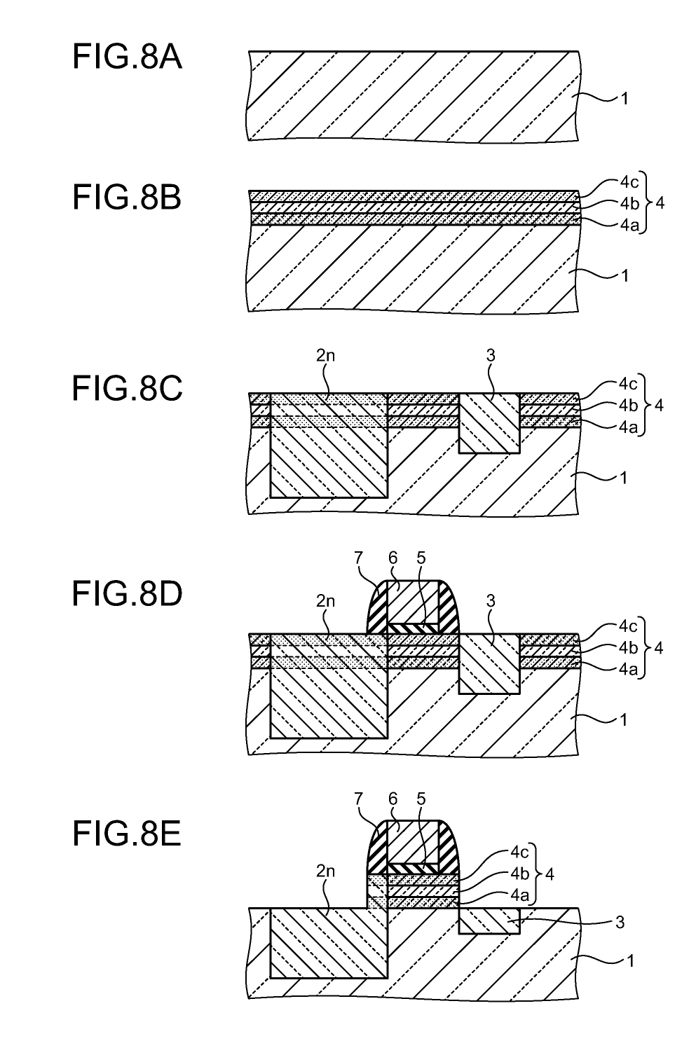

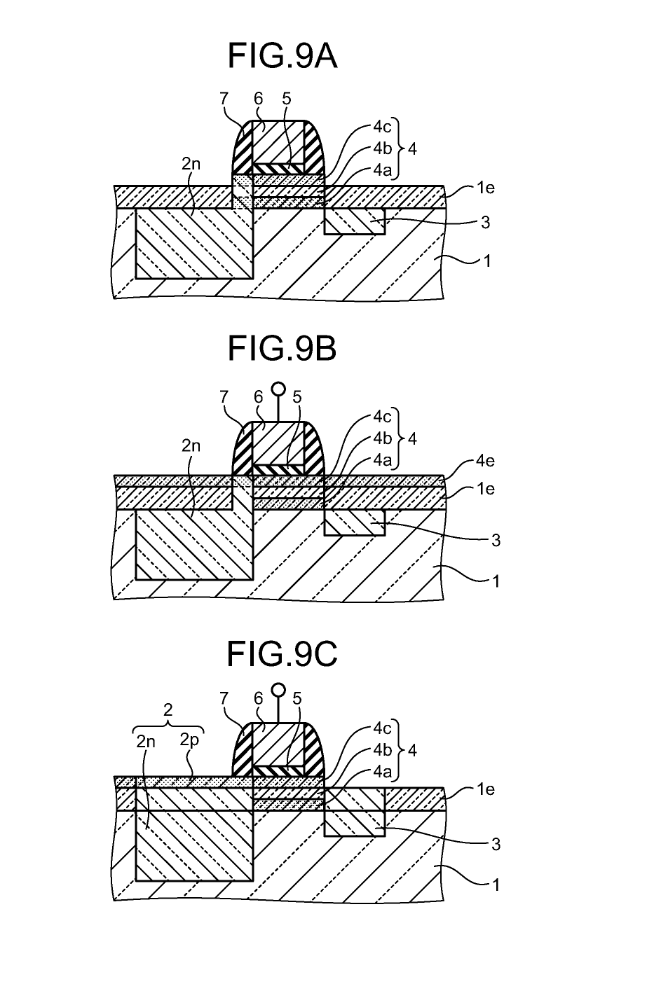

By referring to FIG. 8A to FIG. 8E and FIG. 9A to FIG. 9C, described below will be the manufacturing method of the CMOS image sensor 100 of the present embodiment. Here, of the pixel unit 200 of the CMOS image sensor 100, the process of forming the part around the transfer gate 6 illustrated in FIG. 1 will be described below.

In the manufacturing method of the CMOS image sensor 100 according to the present embodiment, firstly, the p-well 1 is formed on the top surface of a semiconductor substrate such as a single crystal silicon wafer as illustrated in FIG. 8A, for example. The p-well 1 can be formed by ion-injecting a p-type impurity such as B (boron) and the like into the forming position of the p-well 1 in the semiconductor substrate and then performing an anneal process, for example. It is noted that the p-well 1 may be formed by forming the recess portion in the forming position of the p-well 1 in the semiconductor substrate and growing a p-type silicon layer in the recess portion in an epitaxial manner.

Subsequently, as illustrated in FIG. 8B, the SiGe layer 4a as the embedded layer, the Si layer 4b, and the uppermost layer of the SiGe layer 4c are sequentially layered by the epitaxial growth in a predetermined position on the upper surface of the p-well 1. Here, the thickness of the embedded layer of the SiGe layer 4a and the uppermost layer of the SiGe layer 4c is 30 to 100 nm and the concentration of the Ge is greater than or equal to 1% and less than 50%. The intermediate layer of the Si layer 4b is 5 nm to 1 μm.

As illustrated in FIG. 8C, the charge accumulating layer 2n is then formed in the forming position of the photodiode unit 2 in the p-well 1. Specifically, a resist is formed on the upper surface of the p-well 1, and an n-type impurity such as P (phosphorus), for example, is ion-injected into the p-well 1 using the above resist as the mask. Then, after the ion injection of a p-type impurity to the p-well 1 using a resist as the mask, the anneal process is made. Thereby, the charge accumulating layer 2n is formed. In this case, the depth of the charge accumulation layer 2n is approximately 3 μm.

Subsequently, by the same process as the charge accumulating layer 2n, an n-type impurity region that becomes the floating diffusion unit 3 is formed, in the top view, in the region opposing to the charge accumulating layer 2n interposing the region where the transfer gate 6 of the p-well 1 is to be formed. Here again, the floating diffusion unit 3 can be formed by covering with a resist the part other than the forming position of the floating diffusion unit 3, ion-injecting the n-type impurity using a resist as the mask, and then separating the resist to perform the anneal process.

Subsequently, as illustrated in FIG. 8D, the transfer gate 6 is formed via the gate insulating film 5 in a predetermined position on the upper surface of the p-well 1. Specifically, a thin silicon oxide film whose thickness is approximately 5 nm is formed on the upper surface of the p-well 1 and a poly-silicon layer whose thickness is approximately 150 nm is formed on the upper surface of the silicon oxide film. The gate insulating film 5 and the transfer gate 6 are then formed by removing the poly-silicon layer and the silicon oxide film in the unnecessary part by a photolithography and an etching.

Subsequently, the sidewall 7 is formed on the side of the transfer gate 6. For example, the sidewall 7 is formed by patterning the gate insulating film 5 and the transfer gate 6, sequentially forming a silicon oxide film and a silicon nitride film on the entire upper surface of the structure, and then performing an etch-back by a reactive ion etching (RIE).

Then, as illustrated in FIG. 8E, the SiGe layer 4c, the Si layer 4b, and the SiGe layer 4a are sequentially etched using the transfer gate 6 having the sidewall 7 formed thereto as the mask to have the SiGe layer 4c, the Si layer 4b, and the SiGe layer 4a remain in the channel region only.

Further, as illustrated in FIG. 9A, the epitaxial growth on the etched surface is made to form a Si epitaxial layer le.

Further, as illustrated in FIG. 9B, the epitaxial growth on the etched surface is made to form a SiGe epitaxial growth layer 4e.

Finally, the charge accumulating layer 2n forming the photodiode unit 2 is left and covered with a resist, a p-type impurity is ion-injected, a hole accumulating layer 2p of the p-type region is formed on the surface, and the photodiode unit 2 is then obtained as illustrated in FIG. 9C. Providing the hole accumulating layer 2p of the SiGe layer can prevent the leak of the charges, and the generated charges can be carried in a high accuracy, as described in the second embodiment.

The CMOS image sensor 100 is then manufactured by sequentially layering the interlayer insulating film, the color filter (not illustrated), the micro-lens (not illustrated), and so on, and forming the contact unit 8 and the contact plug 9 to the floating diffusion unit 3 to form the pixel unit 200.

As described above, in the manufacturing method of the CMOS image sensor according to the present embodiment, obtained are the advantages of being able to fabricate the CMOS image sensor that allows for the reduction of the random telegraph noise, the reduction of the dark current and the white defect, and the expansion of the dynamic range.

Further, in the floating diffusion unit 3, the SiGe layer 4c, the Si layer 4b, and the SiGe layer 4a are etched away so as to form the contact avoiding the SiGe layer 4c, the Si layer 4b, and the SiGe layer 4a, so that the above-described advantages can be obtained without causing the increase of the contact resistance. It is noted that the etching of the SiGe layer 4c, the Si layer 4b, and the SiGe layer 4a is performed before the transistor is formed and thus the mask is necessary. In the formation of the mask used in the ion implantation process for forming the photodiode, however, there is no unevenness on the surface due to the transistor, which facilitates the focus adjustment of the photolithography and allows for obtaining a highly accurate pattern.

It is noted that it is not necessary to etch and remove the SiGe layer 4c, the Si layer 4b, and the SiGe layer 4a on the entire surface of the floating diffusion unit 3, and the preferable contact can be obtained by etching and removing the SiGe layer 4c, the Si layer 4b, and the SiGe layer 4a at least on the contact unit 8.

### Second Embodiment

While the process of forming the photodiode unit prior to the formation of the transfer gate has been described in the above-described first embodiment, described as the second embodiment will be the process of forming the photodiode unit after the formation of the transfer gate.

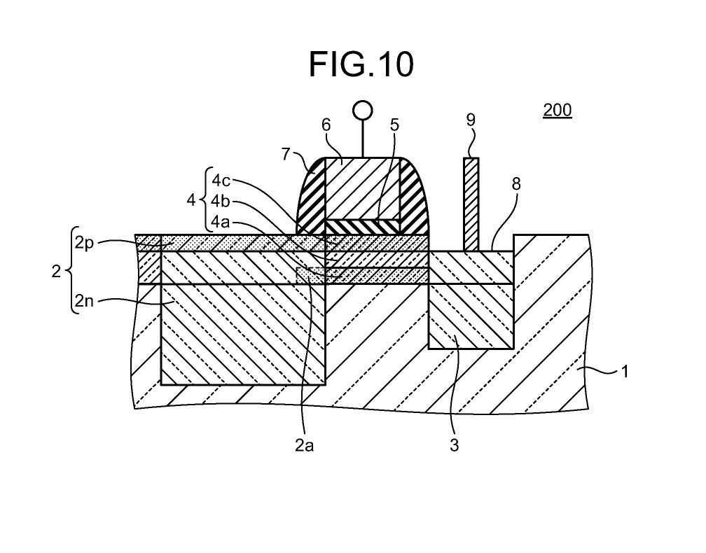

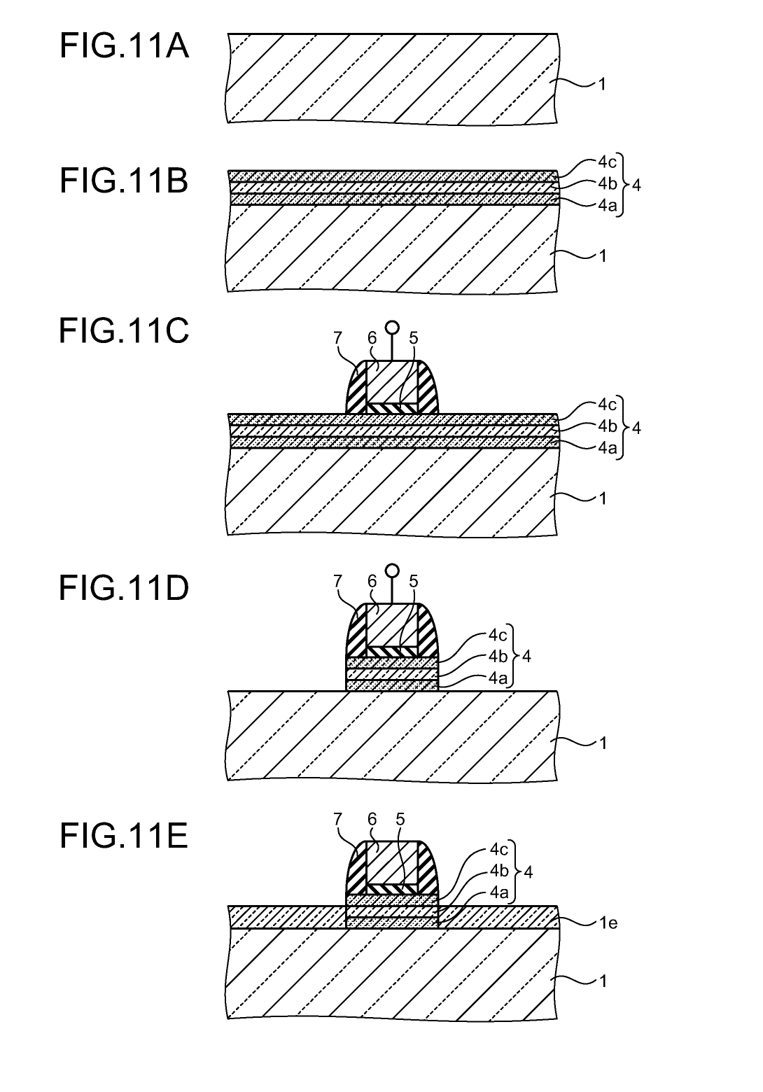

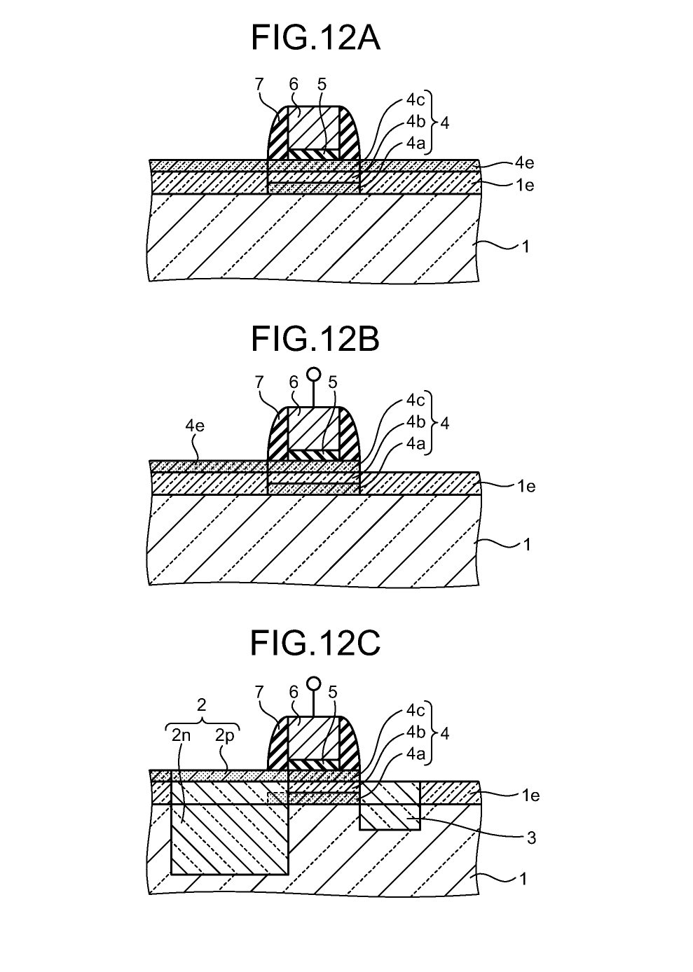

By referring to FIG. 10, FIG. 11A to FIG. 11E, and FIG. 12A to FIG. 12C, described below will be the CMOS image sensor 100 and the manufacturing method thereof according the embodiment. Here again, of the pixel unit 200 of the CMOS image sensor 100, the process for forming the part around the transfer gate will be described. The structure of the CMOS image sensor obtained by this manufacturing process is different from the first embodiment only in that, under the sidewall, there is a residual n-type SiGe layer 2a obtained by introducing the n-type impurity to the SiGe layer 4a, and other features are similar to the CMOS image sensor 100 of the first embodiment.

In the manufacturing method of the CMOS image sensor 100 according to the second embodiment, firstly, as illustrated in FIG. 11A, the p-well 1 is formed on the upper surface of the semiconductor substrate such as the single crystal silicon wafer similarly to the case of the first embodiment, for example.

Subsequently, as illustrated in FIG. 11B, the SiGe layer 4a as the embedded layer, the Si layer 4b, and the uppermost layer of the SiGe layer 4c are sequentially layered by the epitaxial growth in the predetermined position on the upper surface of the p-well 1. The above is the same as the manufacturing process of the CMOS image sensor described in the first embodiment so far.

Subsequently, as illustrated in FIG. 11C, the transfer gate 6 is formed via the gate insulating film 5 to a predetermined position on the upper surface of the p-well 1. Specifically, a thin silicon oxide film whose thickness is approximately 5 nm is formed on the upper surface of the p-well 1 and a poly-silicon layer whose thickness is 150 nm is formed on the upper surface of the silicon oxide film. The gate insulating film 5 and the transfer gate 6 are then formed by removing the poly-silicon layer and the silicon oxide film in the unnecessary part by a photolithography and an etching. Subsequently, the sidewall 7 is formed on the side of the transfer gate 6. For example, the sidewall 7 is formed by patterning the gate insulating film 5 and the transfer gate 6, sequentially forming a silicon oxide film and a silicon nitride film on the entire upper surface of the structure, and then performing an etch-back by a reactive ion etching (RIE).

Then, as illustrated in FIG. 11D, the SiGe layer 4c, the Si layer 4b, and the SiGe layer 4a are sequentially etched using the transfer gate 6 having the sidewall 7 formed thereto as the mask to have the SiGe layer 4c, the Si layer 4b, and the SiGe layer 4a remain in the channel region only.

Further, as illustrated in FIG. 11E, the epitaxial growth on the etched surface is made to form the Si epitaxial layer 1e.

Further, as illustrated in FIG. 12A, the epitaxial growth on the etched surface is made to form the SiGe epitaxial growth layer 4e.

Then, as illustrated in FIG. 12B, the SiGe epitaxial growth layer 4e at the position forming the floating diffusion unit 3 is etched away.

As illustrated in FIG. 12C, the photodiode unit 2 and the floating diffusion unit 3 are then formed. In the formation, firstly, the charge accumulating layer 2n is formed in the forming position of the photodiode unit 2 in the p-well 1. Specifically, a resist is formed on the upper surface of the p-well 1, and an n-type impurity such as P (phosphorus), for example, is ion-injected to the p-well 1 using the resist as the mask. Then, after the ion injection of a p-type impurity to the p-well 1 using the resist as the mask, the anneal process is made. Thereby, the charge accumulating layer 2n is formed and the pn junction is formed with the p-well 1. In this case, the depth of the charge accumulating layer 2n is approximately 3 μm.

Subsequently, by the same process as the charge accumulating layer 2n, the n-type impurity region that becomes the floating diffusion unit 3 is formed in the region opposing to the charge accumulating layer 2n interposing the transfer gate 6 of the p-well 1 in the top view. Here again, the floating diffusion unit 3 can be formed by covering with a resist the part other than the forming position of the floating diffusion unit 3, ion-injecting the n-type impurity using a resist as the mask, and then separating the resist to perform the anneal process.

Finally, the charge accumulating layer 2n forming the photodiode unit 2 is left and covered with a resist, the p-type impurity is ion-injected, the hole accumulating layer 2p of the p-type region is formed on the surface, and the photodiode unit 2 is obtained as illustrated in FIG. 12C. Providing the hole accumulating layer 2p can prevent the leak of the charges, and the generated charges can be carried in a high accuracy.

Similarly to the first embodiment, the CMOS image sensor 100 is then manufactured by sequentially layering the interlayer insulating film, the color filter (not illustrated), the micro-lens (not illustrated), and so on, and forming the contact unit 8 and the contact plug 9 to the floating diffusion unit 3 to form the pixel unit 200.

As described above, also in the manufacturing method of the CMOS image sensor according to the second embodiment, the channel for transferring the charges photoelectrically converted by the photodiode unit 2 to the floating diffusion unit 3 is extremely easily formed with the Si layer 4b surrounded by the SiGe layers 4a and 4c, which allows for obtaining the advantage of achieving the extremely superior charge transfer in the quantum well structure. Further, in the floating diffusion unit 3, the SiGe layer is etched away to form the contact avoiding the SiGe layer, so that the above advantages can be obtained without causing the increase of the contact resistance.

According to this method, the SiGe epitaxial growth layer 4e is etched after the transfer gate is formed, so that covering the gate with the silicon nitride and the like eliminates the need for forming the mask for the etching. However, the mask is necessary to form the photodiode unit 2.

### Third Embodiment

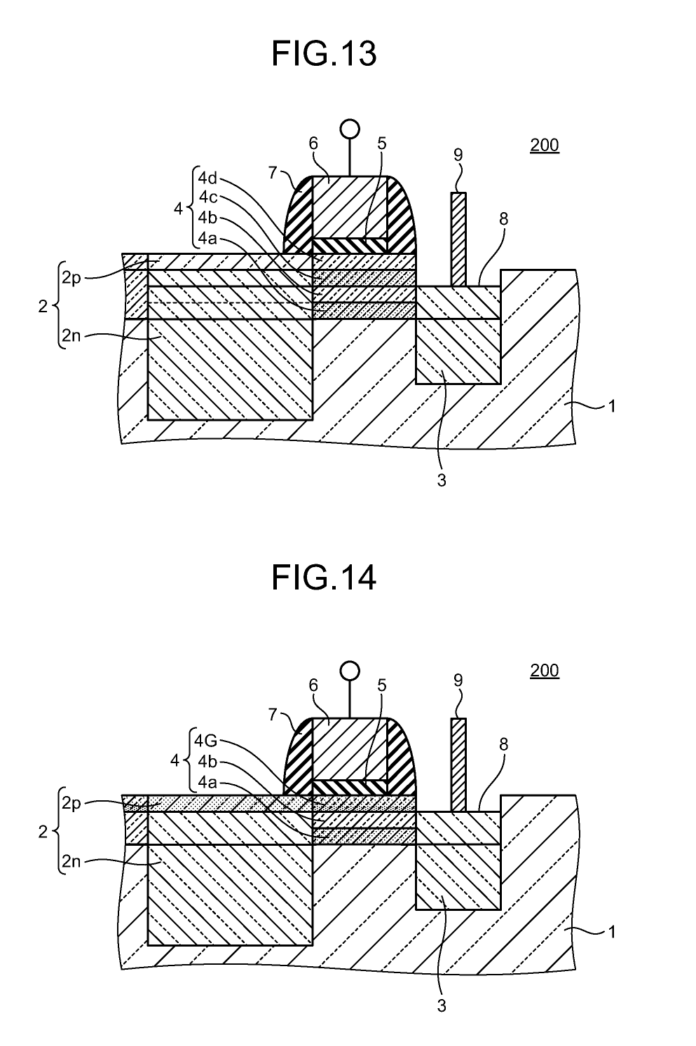

In general, the interface state density of the SiGe/SiO₂ interface is higher than that of the Si/SiO₂. Because of this high interface state density, the mobility may be reduced by the affection of the remote scattering due to the interface state in transferring the electrons in the Si. In this case, in the third embodiment, the insertion of a Si layer 4d between the SiGe/SiO₂ as illustrated in FIG. 13 allows for the reduction of the interface state density. While other features are similar to those in the CMOS image sensor of the first embodiment illustrated in FIG. 1 and thus their description will not be omitted here, the same part is provided with the same reference numeral.

According to this configuration, the Si/SiO₂ interface is replaced with the SiGe/SiO₂ interface, which allows for the reduction of the interface state density and allows for the suppression of the reduction in the mobility which would otherwise be caused by the affection of the remote scattering due to the interface state to improve the operation characteristics compared to the CMOS image sensor of the first embodiment. Also in the present embodiment, it is desirable that the thickness of the SiGe layer 4c be 30 to 100 nm. Thereby, the lattice distortion can be reduced by the lattice relaxation and the transfer path can be obtained with a high reliability. It is further desirable that the thickness of the SiGe layer in the uppermost layer side be thicker than 50 nm. This ensures the reduction of the lattice distortion.

### Fourth Embodiment

While the Si layer 4d is inserted in order to avoid the affection of the remote scattering due to the high interface state density of the SiGe/SiO₂ interface in the third embodiment, the present embodiment employs a grading structure in which the Ge concentration is gradually decreased, in place of the hetero interface of the SiO₂/Si/SiGe. In this grading structure, the uppermost layer of the channel 4 of the transfer gate is a Si_{X}Ge_{1-X} gradient composition layer (X: 0<X<1), the Si gradually decreases from the uppermost surface, and the underlying layer thereof is the SiGe layer. That is, in place of the SiGe layer 4c in the first embodiment, a Si_{1-X}Ge_{X} gradient composition layer (0≦X≦1) 4G is employed as illustrated in FIG. 14. It is here configured that the content ratio of the Ge in the SiGe decreases as it is close to the gate insulating film 5.

While other features are similar to those in the CMOS image sensor of the first embodiment illustrated in FIG. 1 and thus their description will be omitted here, the same part is provided with the same reference numeral.

According to this configuration, the SiGe/SiO₂ interface is replaced with the Si_{1-X}Ge_{X}/SiO₂ gradient composition layer interface, which allows for the reduction of the interface state density and the suppression of the reduction in the mobility by the affection of the remote scattering due to the interface state. Therefore, the operation characteristics can be improved compared to the CMOS image sensor of the first embodiment. In forming the SiGe layer in the epitaxial growth in the manufacturing, it can be easily formed by gradually decreasing the concentration of the gas containing Ge. Further, the small lattice distortion allows for the reduction in the occurrence rate of the defect such as film detachment.

### Fifth Embodiment

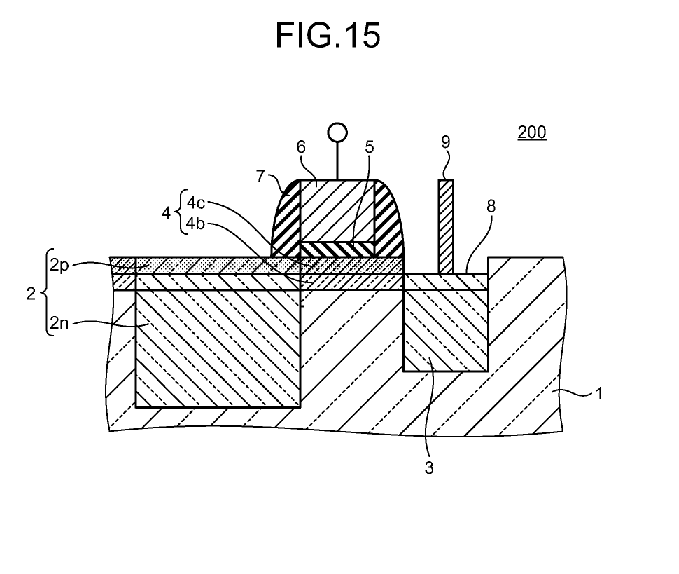

In the CMOS image sensor of the above-described first embodiment, the underlying SiGe layer 4a may be eliminated as illustrated in FIG. 15. In practice, during the operation of the transistor, the quantum well is formed in the inversion layer caused by the bending of the band, so that the electrons in the Si are concentrated to the quantum well and may perform the same function as in the case where the underlying layer SiGe is provided.

While other features are similar to those in the CMOS image sensor of the first embodiment illustrated in FIG. 1 except that the underlying SiGe layer 4a of the channel is omitted and thus their description will be omitted here, the same part is provided with the same reference numeral.

The above configuration allows for the simplified structure resulting in the easier manufacturing.

It is noted that, in the above-described embodiment, the SiGe/Si/SiGe is removed in the floating diffusion unit 3. Thus, in transferring the electrons from the floating diffusion unit to the amplifier transistor, which can prevent the SiGe from being the electronic barrier causing not only the reduction of the transfer speed but also the occurrence of the situation where the full transfer cannot be made. However, the floating diffusion structure also may be the SiGe/Si/SiGe structure without being etched away. As a result, there is a case where the electronic barrier causes not only the reduction of the transfer speed but also the occurrence of the situation where the full transfer cannot be made in transferring the electrons to the amplifier transistor from the floating diffusion unit. In this case, the transfer gate transistor can prevent the asymmetrical structure between the photodiode unit 2 and the floating diffusion unit 3.

Furthermore, although the underlying layer SiGe in the photodiode unit 2 is etched away in the above-described embodiment because it serves as the electronic barrier in transferring the electrons to the Si layer, the underlying layer SiGe layer 4c may be left.

As described above, the above-described embodiments allow for achieving the reduction of the random noise, the reduction of the dark current and the white defect, the improvement of the number of saturated electrons, and the improvement of the dynamic range of the CMOS image sensor.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising a CMOS image sensor, the CMOS image sensor comprising:
a plurality of photoelectric conversion units adapted to photoelectrically convert an incident light into signal charges; and
a transfer unit which comprises a transfer gate under which a channel region is formed, adapted to transfer the signal charges generated by the photoelectric conversion unit to a floating diffusion unit from the photoelectric conversion unit through the channel region,
wherein the channel portion of the transfer gate of the transfer unit has at least one SiGe layer.

2. The semiconductor device according to claim 1, wherein the SiGe layer is extended to the floating diffusion unit, and is fully removed in at least a contact region of the floating diffusion unit.

3. The semiconductor device according to claim 1, wherein the photoelectric conversion unit comprises a photodiode unit, and the SiGe layer is provided in an upper layer of the photodiode unit.

4. The semiconductor device according to claim 1, wherein an uppermost layer of the channel portion of the transfer gate is a Si layer, and its lower layer is a SiGe layer.

5. The semiconductor device according to claim 1, wherein the uppermost layer of the channel portion of the transfer gate is a Si_{X}Ge_{1-X} gradient composition layer (X: 0<X<1), Si gradually decreases from an uppermost surface, and its lower layer is a SiGe layer.

6. The semiconductor device according to claims 1, wherein the channel portion of the transfer gate has a three-layer structure of a SiGe layer, a Si layer, and a SiGe layer from uppermost layer side.

7. The semiconductor device according to claim 6, wherein a thickness of the SiGe layer of the uppermost layer side is 30 to 100 nm.

8. The semiconductor device according to claim 6, wherein a thickness of the SiGe layer of the uppermost layer side is thicker than 50 nm.

9. The semiconductor device according to claim 4, wherein the channel portion of the transfer gate has a four-layer structure of a Si layer, a SiGe layer, a Si layer, and a SiGe layer in order from uppermost layer side.

10. The semiconductor device according to claim 5, wherein a concentration of Ge of the Si_{X}Ge_{1-X} gradient composition layer (X: 0<X<1) is greater than or equal to 1% to less than 50%.

11. The semiconductor device according to claim 1, wherein the channel portion of the transfer gate has a two-layer structure of a SiGe layer and a Si layer from uppermost layer side.

12. The semiconductor device according to claim 11, wherein a thickness of the SiGe layer of the uppermost layer side is 30 to 100 nm.

13. The semiconductor device according to claim 11, wherein a thickness of the SiGe layer of the uppermost layer side is thicker than 50 nm.

14. A manufacturing method of a semiconductor device comprising:
forming, on a semiconductor substrate of a conductive type, a plurality of photoelectric conversion units adapted to photoelectrically convert an incident light into signal charges;
forming a floating diffusion unit; and
forming a transfer gate of a transfer unit between the photoelectric conversion unit and the floating diffusion unit,
wherein the forming of the transfer gate includes
forming a channel portion having at least one SiGe layer, and
forming a contact to the floating diffusion unit avoiding the SiGe layer.

15. The manufacturing method of the semiconductor device according to claim 14, wherein the forming of the photoelectric conversion unit is performed before the forming of the transfer gate.

16. The manufacturing method of the semiconductor device according to claim 14, wherein the forming of the photoelectric conversion unit is performed after the forming of the transfer gate.

17. The manufacturing method of the semiconductor device according to claim 14, wherein the SiGe layer on the photoelectric conversion unit is etched away after the forming of the transfer gate.

18. The manufacturing method of the semiconductor device according to claim 14, wherein the SiGe layer on a contact region on the photoelectric conversion unit is selectively etched away after the forming of the transfer gate.

19. The semiconductor device according to claim 2, wherein an uppermost layer of the channel portion of the transfer gate is a Si layer, and its lower layer is a SiGe layer.

20. The semiconductor device according to claim 3, wherein an uppermost layer of the channel portion of the transfer gate is a Si layer, and its lower layer is a SiGe layer.
